(19) United States
(12) Patent Application Publication
(10) Pub. No.: US 2016/0081226 A1
(43) Pub. Date: Mar. 17, 2016

(54) HEAT DISSIPATION STRUCTURE FOR MOBILE DEVICE

(71) Applicant: ASIA VITAL COMPONENTS CO., LTD., NEW TAIPEI CITY (TW)

(72) Inventor: Kuei-Feng Chiang, New Taipei City (TW)

(21) Appl. No.: 14/483,162

(22) Filed: Sep. 11, 2014

(51) Int. Cl. H05K 7/20

(52) U.S. Cl. CPC H05K 7/20427

(57) ABSTRACT

A heat dissipation structure for mobile device includes an element holding member internally defining a first receiving space, in which a plurality of electronic elements of a mobile device is mounted; and a heat dissipation layer formed on at least one side of each of the electronic elements. The heat dissipation layer is formed on one side of each of the electronic elements through a micro arc oxidation (MAO) process, a plasma electrolytic oxidation (PEO) process, an anodic spark deposition (ASD) process, or an anodic oxidation by spark deposition (ANOF) process. Therefore, heat produced by the electronic elements in the mobile device can be quickly removed away from the electronic elements via the heat dissipation layer.

### FIELD OF THE INVENTION

The present invention relates to a heat dissipation structure for mobile device, and more particularly to a heat dissipation structure for mobile device designed to increase the heat dissipation efficiency of electronic elements in a mobile device.

### BACKGROUND OF THE INVENTION

Most of the currently available mobile devices, such as notebook computers, tablet computers and smartphones, have a slim body and a largely increased computing speed. The electronic elements in the mobile devices for executing the computation at high speed also produce a large amount of heat during operation thereof. For the purpose of being conveniently portable, the mobile devices have a largely reduced overall thickness. And, to prevent invasion by foreign matters and moisture, the mobile devices are provided with only an earphone port and some necessary connection ports but not other open holes that allow air convection between the narrow internal space of the mobile devices and the external environment. Therefore, due to the small thickness of the mobile devices, the large amount of heat produced by the electronic elements in the mobile devices, such as the computation executing units and the battery, can not be quickly dissipated into the external environment. Further, due to the closed narrow internal space of the mobile devices, it is difficult for the heat produced by the electronic elements to dissipate through air convection. As a result, heat tends to accumulate or gather in the mobile devices to adversely affect the working efficiency or even cause crash of the mobile devices.

To solve the above problems, some passive type heat dissipation elements, such as heat spreader, vapor chamber, heat sink, etc., are mounted in the mobile devices to assist in heat dissipation thereof. Due to the small thickness and the narrow internal space of the mobile devices, these passive type heat dissipation elements must also be extremely thin to be mounted in the very limited internal space of the mobile devices. However, the wick structure and the vapor passage in the size reduced heat spreader and vapor chamber are also reduced in size to result in largely lowered heat transfer efficiency of the heat spreader and the vapor chamber and accordingly poor heat dissipation performance thereof. In brief, when the internal computing units of the mobile devices have an extremely high power, the conventional heat spreader and vapor chambers just could not effectively dissipate the heat produced by the high power computing units.

In view that the mobile devices have a narrow internal space and have a plurality of electronic elements densely mounted in the narrow space, and the heat produced by the electronic elements during operation tends to accumulate in the narrow receiving space of the mobile devices without being easily transferred to an outer side of the mobile devices for dissipation, it is obviously important to work out a way for effectively remove the heat from the narrow internal space of the mobile devices.

### SUMMARY OF THE INVENTION

A primary object of the present invention is to provide a heat dissipation structure for mobile device to overcome the drawbacks in the prior art. To achieve the above and other objects, the heat dissipation structure for mobile device according to the present invention includes an element holding member internally defines a first receiving space, in which a plurality of electronic elements of a mobile device is mounted; and a heat dissipation layer formed on at least one side of each of the electronic elements. The heat dissipation layer is formed on one side of each electronic element through a micro arc oxidation (MAO) process, a plasma electrolytic oxidation (PEO) process, an anodic spark deposition (ASD) process, or an anodic oxidation by spark deposition (ANOF) process. Therefore, heat produced by the electronic elements in the mobile device can be quickly removed away from the electronic elements via the heat dissipation layer.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a heat dissipation structure for mobile device according to a first embodiment of the present invention;

FIG. 2 is an assembled sectional view of the heat dissipation structure for mobile device according to the first embodiment of the present invention;

FIG. 3 is an assembled sectional view of a heat dissipation structure for mobile device according to a second embodiment of the present invention;

FIG. 4 is an exploded perspective view of a heat dissipation structure for mobile device according to a third embodiment of the present invention; and

FIG. 5 is an exploded perspective view of a heat dissipation structure for mobile device according to a fourth embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

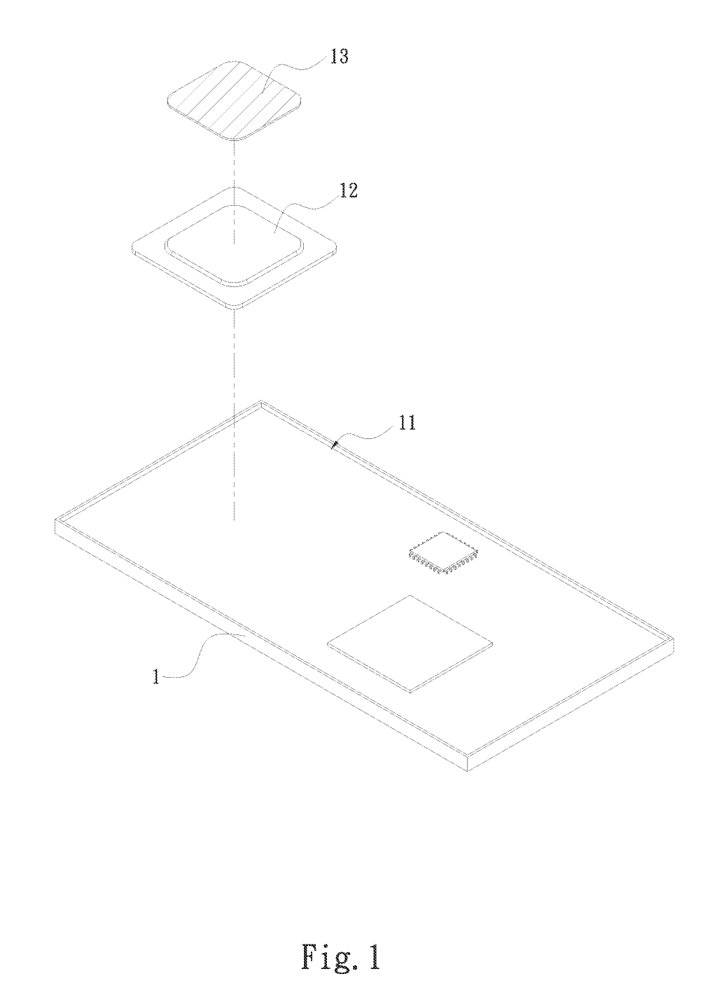

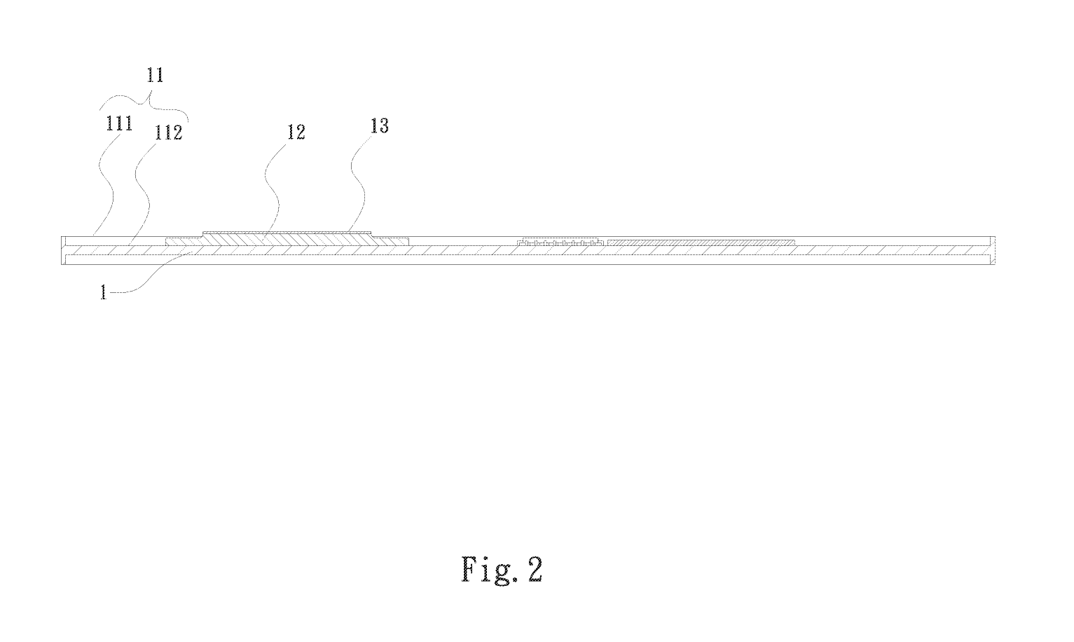

Please refer to FIGS. 1 and 2 that are exploded perspective and assembled sectional views, respectively, of a heat dissipation structure for mobile device according to a first embodiment of the present invention. As shown, the heat dissipation structure for mobile device includes an element holding member 1.

The element holding member 1 internally defines a first receiving space 11, in which a plurality of electronic elements 12 of a mobile device is mounted. The electronic elements 12 respectively have at least one side formed with a heat dissipation layer 13. The heat dissipation layer 13 is formed on one side of each electronic element through micro arc oxidation (MAO) process, plasma electrolytic oxidation (PEO) process, anodic spark deposition (ASD) process, or anodic oxidation by spark deposition (ANOF) process. The element holding member 1 can be formed of a metal sheet, such as an aluminum sheet, an aluminum copper alloy sheet or a stainless steel sheet, or can be formed of other types of sheets, such as a sheet molded by way of powder metallurgy or a sheet molded by way of plastic injection molding. In the illustrated first embodiment, the electronic element 12 is a central processing unit (CPU) or a micro control unit (MCU).

The first receiving space 11 has an open side 111 and a closed side 112. The electronic elements 12 respectively have a bottom side corresponding to the closed side 112 of the first receiving space 11, and a top side corresponding to the open side 111 of the first receiving space 11. That is, the top side of each electronic element 12 corresponding to the open side 111 of the first receiving space 11 is a free end surface, on which the heat dissipation layer 13 is formed. By forming the heat dissipation layer 13 on the free end surface of each of the electronic elements 12 mounted in the first receiving space 11, heat produced by the electronic elements 12 can be quickly removed from the electronic elements 12.

The heat dissipation layer 13 can be formed of a ceramic material or a graphite material, and can be of a porous structure or a nanostructure. And, the heat dissipation layer 13 preferably has a black color, a matt black color, or a dark color. In the illustrated first embodiment, the heat dissipation layer 13 is formed of a ceramic material. However, it is understood the ceramic material is only illustrative and not intended to limit the present invention in any way. Further, the ceramic material for the heat dissipation layer 13 can be of a high-radiation ceramic structure or a high-rigidity ceramic structure.

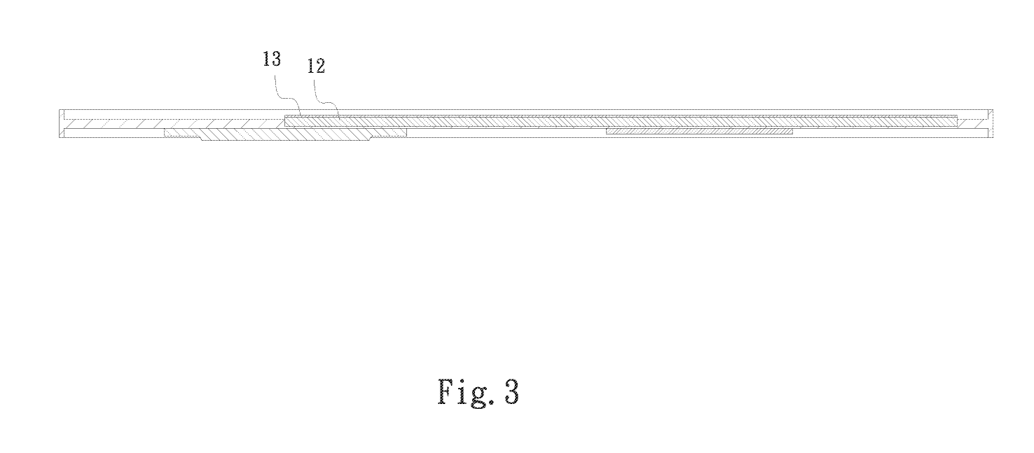

FIG. 3 is an assembled sectional view of a heat dissipation structure for mobile device according to a second embodiment of the present invention. As shown, the second embodiment is generally structurally similar to the first embodiment, except that the electronic element 12 illustrated in the second embodiment is a battery. The heat dissipation layer 13 is formed on a free end surface of the battery to enable quick removal of the produced heat away from the battery.

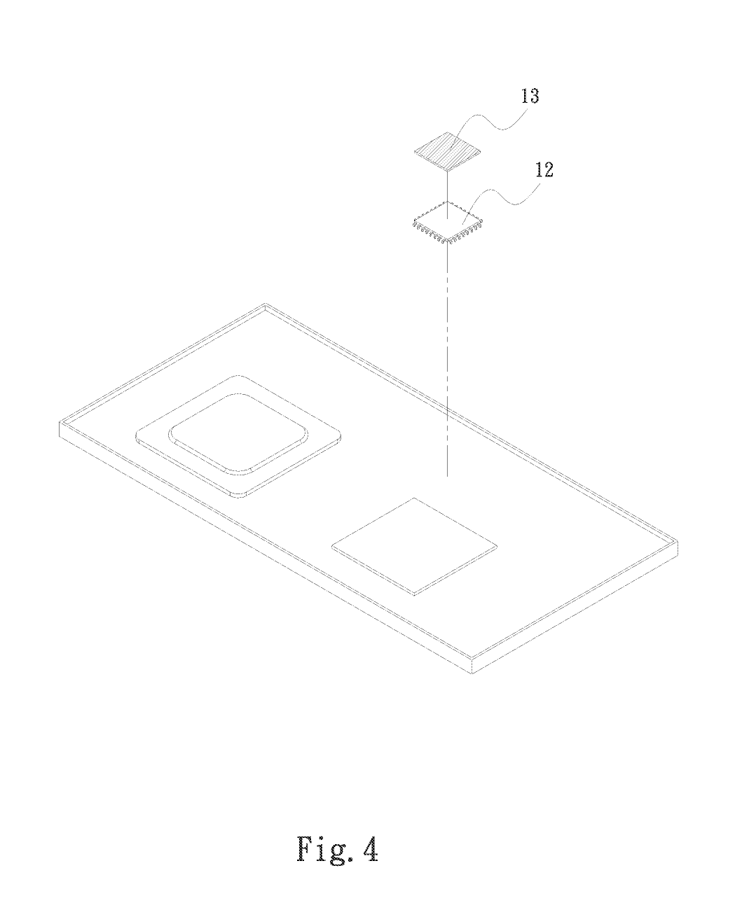

FIG. 4 is an exploded perspective view of a heat dissipation structure for mobile device according to a third embodiment of the present invention. As shown, the third embodiment is generally structurally similar to the first embodiment, except that the electronic element 12 illustrated in the third embodiment is a transistor. The heat dissipation layer 13 is formed on a free end surface of the transistor to enable quick removal of the produced heat away from the transistor.

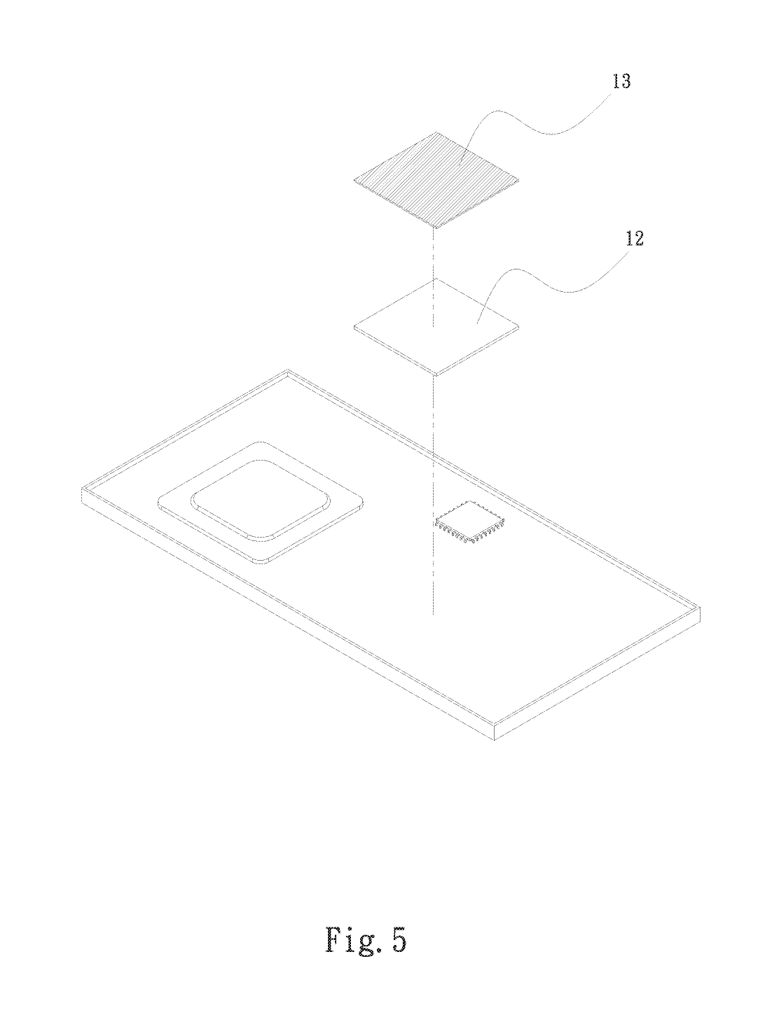

FIG. 5 is an exploded perspective view of a heat dissipation structure for mobile device according to a fourth embodiment of the present invention. As shown, the fourth embodiment is generally structurally similar to the first embodiment, except that the electronic element 12 illustrated in the fourth embodiment is a flash memory. The heat dissipation layer 13 is formed on a free end surface of the flash memory to enable quick removal of the produced heat away from the flash memory.

In view that the heat produced by the electronic elements mounted in the mobile device tends to accumulated in the narrow and closed internal space of the mobile device to cause damage to the mobile device, the present invention is provided mainly to solve the heat dissipation problem of the mobile device. By forming the heat dissipation layer 13 on an open side of each electronic element 12 in the mobile device, the electronic element 12 can have largely increased heat dissipation efficiency to avoid accumulation of the produced heat in the mobile device.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A heat dissipation structure for mobile device, comprising:
an element holding member internally defining a first receiving space, in which a plurality of electronic elements of a mobile device is mounted; and
a heat dissipation layer being formed on at least one side of each of the electronic elements through a process selected from the group consisting of a micro arc oxidation (MAO) process, a plasma electrolytic oxidation (PEO) process, an anodic spark deposition (ASD) process, and an anodic oxidation by spark deposition (ANOF) process.

2. The heat dissipation structure for mobile device as claimed in claim 1, wherein the electronic elements are respectively selected from the group consisting of a transistor, a battery, a central processing unit and a flash memory.

3. The heat dissipation structure for mobile device as claimed in claim 1, wherein the element holding member is formed of a sheet material selected from the group consisting of an aluminum sheet, an aluminum copper alloy sheet, a stainless steel sheet, a sheet molded by way of powder metallurgy, and a sheet molded by way of plastic injection molding.

4. The heat dissipation structure for mobile device as claimed in claim 1, wherein the heat dissipation layer is formed of a material selected from the group consisting of a ceramic material and a graphite material.

5. The heat dissipation structure for mobile device as claimed in claim 1, wherein the heat dissipation layer is of a structure selected from the group consisting of a porous structure and a nanostructure.

6. The heat dissipation structure for mobile device as claimed in claim 1, wherein the heat dissipation layer has a color selected from a black color, a matt black color and a dark color.

7. The heat dissipation structure for mobile device as claimed in claim 1, wherein the heat dissipation layer is of a structure selected from a group consisting of a high-radiation ceramic structure and a high-rigidity ceramic structure.

8. The heat dissipation structure for mobile device as claimed in claim 1, wherein the first receiving space has an open side and a closed side, and the electronic elements respectively have one side corresponding to the closed side of the first receiving space and another side corresponding to the open side of the first receiving space; and the side of each of the electronic elements corresponding to the open side of the first receiving space being a free end surface, and the heat dissipation layer being formed on the free end surface of the electronic elements.
